(19) United States
(12) Patent Application Publication
(10) Pub. No.: US 2015/0212360 A1
(43) Pub. Date: Jul. 30, 2015

(54) DISPLAY DEVICE AND MANUFACTURING METHOD THEREOF

(71) Applicant: Samsung Display Co., Ltd., Yongin-City (KR)

(72) Inventors: Sang-Gu LEE, Hwaseong-si (KR); Su Jeong KIM, Seoul (KR); Yun JANG, Hwaseong-si (KR); Ji-Hoon KIM, Hwaseong-si (KR); Beong-Hun BEON, Hwaseong-si (KR); Na Young SHIN, Hwaseong-si (KR); Seung Hee LEE, Hwaseong-si (KR)

(21) Appl. No.: 14/445,270

(22) Filed: Jul. 29, 2014

(30) Foreign Application Priority Data
Jan. 29, 2014 (KR) 10-2014-0011724

(51) Int. Cl. G02F 1/1347; G02F 1/1341; G02F 1/1333; H01L 27/12; G02F 1/1368

(52) U.S. Cl. CPC G02F 1/13475; H01L 27/1292; G02F 1/1368; G02F 1/133377; G02F 1/1341

(57) ABSTRACT

A display device includes a substrate on which a thin film transistor is positioned, a pixel electrode positioned on the thin film transistor and connected to the thin film transistor, a roof layer separated from the pixel electrode via a microcavity interposed therebetween, and a liquid crystal layer positioned in the microcavity and including a liquid crystal material and a dichroic dye.

This application claims priority to Korean Patent Application No. 10-2014-0011724, filed on Jan. 29, 2014, and all the benefits accruing therefrom under 35 U.S.C. §119, the entire contents of which are incorporated herein by reference.

### BACKGROUND

(a) Technical Field

The invention relates to a display device and a manufacturing method thereof.

(b) Description of the Related Art

A liquid crystal display (“LCD”) is one of the most commonly used flat panel displays. The LCD applies different potentials to a pixel electrode and a common electrode of a liquid crystal panel in which a liquid crystal layer is formed between a lower panel and an upper panel to generate an electric field such that an arrangement of liquid crystal molecules of the liquid crystal layer is realigned and the polarization of incident light is controlled, thereby displaying images.

Two panels forming the liquid crystal panel of the LCD may include the lower panel in which a thin film transistor (“TFT”) is arranged and the upper panel facing the lower panel. In the lower panel, a gate line transmitting a gate signal, a data line transmitting a data signal, a TFT connected to the gate line and the data line, and a pixel electrode connected to the TFT are formed. In the upper substrate, a light blocking member, a color filter, and a common electrode may be formed, and at least one of them may be formed in the lower panel.

In general, in the LCD, two substrates are used for the lower panel and the upper panel, and processes for forming the above-described constituent elements in each substrate and combining the two panels are required. As a result, the liquid crystal panel is heavy and thick, and cost and process time problems are recognized. Recently, a technique in which a plurality of microcavities of a tunnel shape structure is formed on one substrate and the liquid crystal is injected inside the structure to manufacture the display device has been developed. In this display device, the color filter is generally formed between the substrate and the microcavity or on the microcavity.

### SUMMARY

The invention provides a display device realizing various colors without color filter of a thin film in a display device including one substrate, and a manufacturing method thereof.

The invention provides a manufacturing method of a display device without using photolithography to provide a color filter.

A display device according to an exemplary embodiment of the invention includes a substrate on which a thin film transistor (“TFT”) is positioned, a pixel electrode positioned on the TFT and connected to the TFT, a roof layer positioned to be separated from the pixel electrode via a microcavity on the pixel electrode, and a liquid crystal layer positioned in the microcavity and including a liquid crystal material and a dichroic dye.

In an exemplary embodiment, the dichroic dye may be combined with the liquid crystal material at a concentration of about 0.1 weight percent (wt %) to about 15 wt % with respect to a total weight of the liquid crystal layer.

In an exemplary embodiment, the dichroic dye may be a material which absorbs a wavelength range corresponding to one of cyan, magenta, and yellow.

In an exemplary embodiment, the dichroic dye may include at least one of azo dyes, anthraquinone dyes, perylene dyes, merocyanine dyes, azomethine dyes, phthaloperylene dyes, indigo dyes, dioxadine dyes, polythiophene dyes, and phenoxazine dyes.

In an exemplary embodiment, injection holes may be respectively defined at facing edges of the microcavity.

In an exemplary embodiment, one of the injection holes of the microcavity may be substantially blocked so that a material providing the liquid crystal layer is not injectable therein.

In an exemplary embodiment, a plurality of microcavities may be disposed in a matrix form, the liquid crystal layer including a first dichroic dye configured to display a color may be positioned in microcavities of the plurality of microcavities adjacent in a column direction, and the liquid crystal layer including a second dichroic dye configured to display a different color from the first dichroic dye may be positioned in microcavities of the plurality of microcavities adjacent in a row direction.

In an exemplary embodiment, the microcavity may be disposed in a matrix form, the liquid crystal layer including a first dichroic dye configured to display the same color may be positioned in microcavities of the plurality of microcavities adjacent in a row direction, and the liquid crystal layer including a second dichroic dye configured to display a different color may be positioned in the microcavities of the plurality of microcavities adjacent in a column direction.

In an exemplary embodiment, a common electrode positioned between the microcavity and the roof layer may be further included.

A method of manufacturing of a display device according to one exemplary embodiment of the invention is provided. The method includes disposing a TFT on a substrate, providing a pixel electrode connected to the TFT, disposing a sacrificial layer on the pixel electrode, disposing a roof layer on the sacrificial layer, removing the sacrificial layer to define injection holes of a microcavity, and injecting a combination material of which a dichroic dye is combined with a liquid crystal material through the injection holes to provide a liquid crystal layer in the microcavity.

In an exemplary embodiment, the dichroic dye may be combined with the liquid crystal material at a concentration of about 0.1 wt % to about 15 wt % with respect to a total weight of the liquid crystal layer.

In an exemplary embodiment, the dichroic dye may be a material absorbing a wavelength range corresponding to one of cyan, magenta, and yellow.

In an exemplary embodiment, the dichroic dye may include at least one of azo dyes, anthraquinone dyes, perylene dyes, merocyanine dyes, azomethine dyes, phthaloperylene dyes, indigo dyes, dioxadine dyes, polythiophene dyes, and phenoxazine dyes.

In an exemplary embodiment, the combination material may be injected through the injection holes respectively positioned at facing edges of the microcavity.

In an exemplary embodiment, the combination material may be injected through one of the injection holes of the microcavity.

In an exemplary embodiment, the microcavity may be in a matrix form, and the combination material may be injected according to a row direction.

In an exemplary embodiment, the microcavity may be in a matrix form, and the combination material may be injected according to a column direction.

In an exemplary embodiment, the method may further include disposing a common electrode on the sacrificial layer before disposing the roof layer on the sacrificial layer.

According to the invention, photolithography to provide the color filter may be omitted such that a process time may be effectively reduced and a manufacturing cost may be effectively reduced.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a top plan view of a display device according to an exemplary embodiment of the invention.

FIG. 2 is a cross-sectional view taken along line II-II of FIG. 1.

FIG. 3 is a cross-sectional view taken along line III-III of FIG. 1.

FIGS. 4 to 15 are cross-sectional views of an exemplary embodiment of a method for manufacturing a display device according to the invention.

FIGS. 16 to 18 are perspective views schematically showing an exemplary embodiment of a liquid crystal injection method in a display device according to the invention.

### DETAILED DESCRIPTION

In the following detailed description, only certain exemplary embodiments of the invention have been shown and described, simply by way of illustration. As those skilled in the art would realize, the described embodiments may be modified in various different ways, all without departing from the spirit or scope of the invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Now, a display device according to an exemplary embodiment of the invention will be described with reference to accompanying drawings.

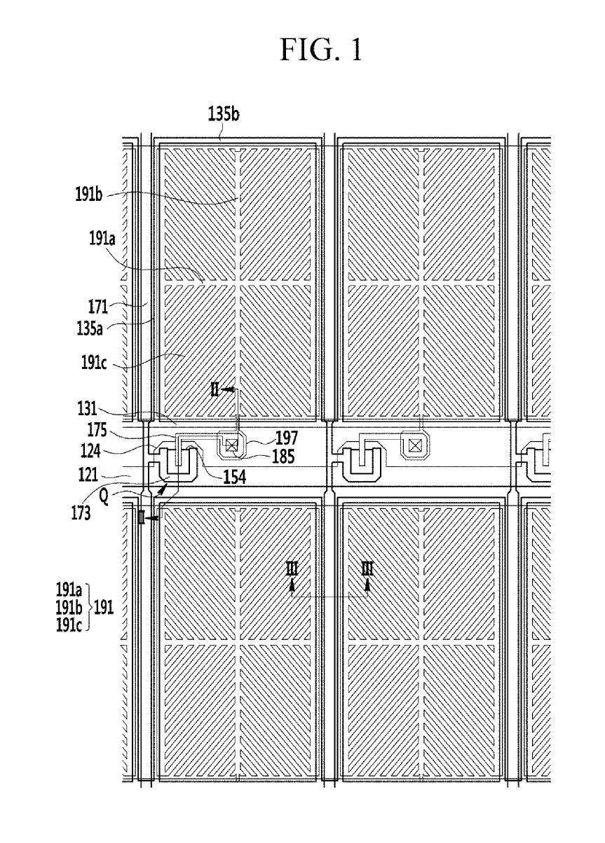

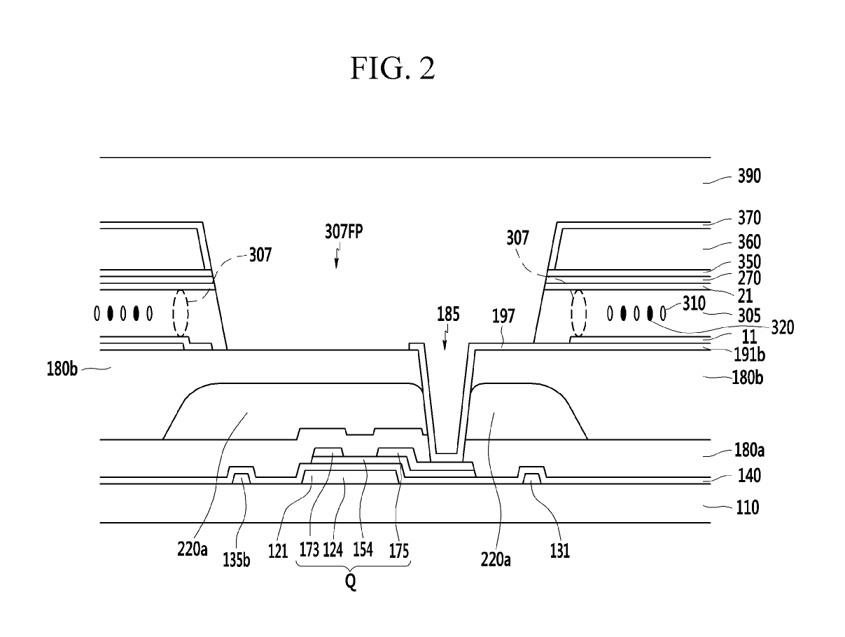

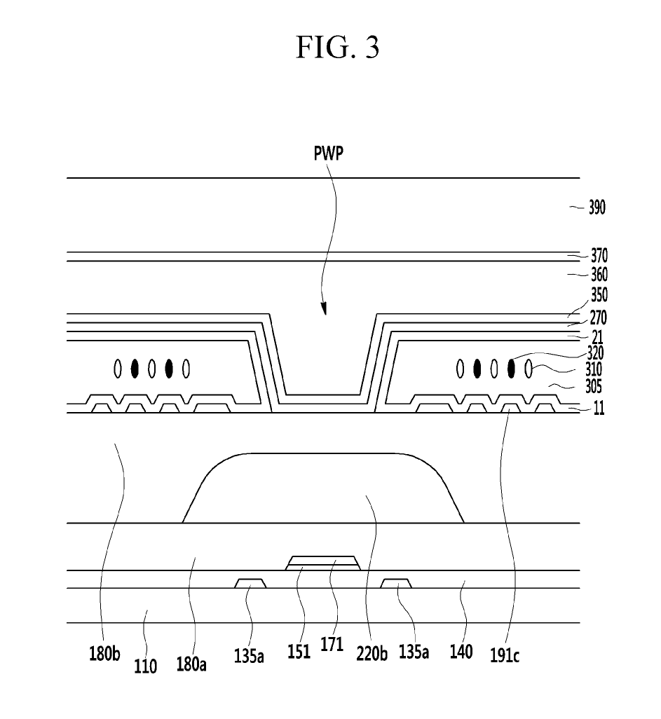

FIG. 1 is a top plan view of a display device according to an exemplary embodiment of the invention, FIG. 2 is a cross-sectional view taken along line II-II of FIG. 1, and FIG. 3 is a cross-sectional view taken along line III-III of FIG. 1.

FIG. 1 shows four adjacent pixel areas. A plurality of pixel areas is disposed in a matrix shape including a plurality of pixel rows and a plurality of pixel columns.

Referring to FIGS. 1 to 3, a gate conductor including a gate line 121 and a storage electrode line 131 is disposed on a substrate 110 including a transparent insulator such as glass or plastic.

The gate line 121 transfers a gate signal and extends in a substantially transverse direction. The gate line 121 includes a gate electrode 124 protruding from the gate line 121. The protrusion shape of the gate electrode 124 may be changed.

The storage electrode lines 131 are extended in the substantially transverse direction, and transfer a predetermined voltage such as a common voltage. The storage electrode line 131 includes a pair of longitudinal portions 135a substantially extending perpendicular to the gate line 121, and a transverse portion 135b connecting ends of the pair of longitudinal portions 135a. The longitudinal portions 135a and the transverse portion 135b may substantially enclose a pixel electrode 191.

A gate insulating layer 140 is disposed on the gate line 121 and the storage electrode line 131. In an exemplary embodiment, the gate insulating layer 140 may include an inorganic insulating material such as a silicon nitride (SiNx) and a silicon oxide (SiOx). Further, the gate insulating layer 140 may include a single layer or a multilayer.

A semiconductor 151 positioned under the data line 171 and a semiconductor 154 positioned under source/drain electrodes 173 and 175 and at a channel portion of a thin film transistor (“TFT”) Q are disposed on the gate insulating layer 140. In an exemplary embodiment, the semiconductors 151 and 154 may include amorphous silicon, polycrystalline silicon, or a metal oxide.

An ohmic contact (not shown) may be disposed between the semiconductor 151 and the data line 171 and between the semiconductors 154 and the source/drain electrodes 173 and 175, respectively. In an exemplary embodiment, the ohmic contact may include a material such as n+ hydrogenated amorphous silicon in which an n-type impurity is doped with a high concentration, or of a silicide, for example.

A data conductor including a source electrode 173, a drain electrode 175, and a data line 171 connected to the source electrode 173 is disposed on the semiconductors 151 and 154 and the gate insulating layer 140.

The data lines 171 transmit data signals, and extend in a substantially vertical direction so as to cross the gate lines 121. The source electrode 173 and the drain electrode 175 provide a TFT Q along with the gate electrode 124 and the semiconductor 154, and the channel of the TFT Q is provided in the semiconductor 154 between the source electrode 173 and the drain electrode 175.

A first interlayer insulating layer 180a is disposed on the data conductors 171, 173, and 175 and the exposed portion of the semiconductor 154. In an exemplary embodiment, the first interlayer insulating layer 180a may include the inorganic insulator such as a silicon nitride (SiNx) and a silicon oxide (SiOx), or the organic insulator.

Light blocking members 220a and 220b are disposed on the first interlayer insulating layer 180a. The light blocking members 220a and 220b have a lattice structure defining an opening corresponding to a region displaying an image therein, and includes a material preventing light from being transmitted therethrough. The light blocking members 220a and 220b include a transverse light blocking member 220a provided in a direction parallel to the gate line 121, and a longitudinal light blocking member 220b provided in a direction parallel to the data line 171. In an exemplary embodiment, the light blocking member 220 may be disposed on an upper insulating layer 370 that will be described later.

A second interlayer insulating layer 180b covering the light blocking member 220 is disposed thereon. In an exemplary embodiment, the second interlayer insulating layer 180b may include the inorganic insulator such as a silicon nitride (SiNx) and a silicon oxide (SiOx) or the organic insulator. As shown in FIGS. 2 and 3, in the case where a step occurs due to a thickness of the light blocking members 220a or 220b, the second interlayer insulating layer 180b includes the organic insulator, thus reducing or removing the step.

A contact hole 185 exposing the drain electrode 175 is defined in the light blocking member 220a and the interlayer insulating layer 180a or in the light blocking member 220b and the interlayer insulating layer 180b.

The pixel electrode 191 is disposed on the second interlayer insulating layer 180b. In an exemplary embodiment, the pixel electrode 191 may include a transparent conductive material such as indium tin oxide (“ITO”) and indium zinc oxide (“IZO”).

In an exemplary embodiment, an entire shape of the pixel electrode 191 may be a quadrangle in a plan view. The pixel electrode 191 includes a cross stem that is configured of a transverse stem 191a and a longitudinal stem 191b intersecting the transverse stem 191a. Further, the pixel electrode 191 has four sub-regions provided by the horizontal stem 191a and the vertical stem 191b, and each of the sub-regions includes a plurality of minute branch portions 191c. Also, in the illustrated exemplary embodiment, the pixel electrode 191 further includes an outer stem enclosing the periphery thereof.

The minute branch portions 191c of the pixel electrode 191 may provide an angle of about 40 degrees to 45 degrees with respect to the gate line 121 or the transverse stem 191a. In an exemplary embodiment, the minute branches of two neighboring sub-regions may be crossed. In an exemplary embodiment, a width of each minute branch may be gradually increased, or a distance between the minute branches 191c may be varied.

The pixel electrode 191 includes an extension 197 which is connected at a lower end of the vertical stem 191b and has a larger area than the vertical stem 191b. The pixel electrode 191 is physically and electrically connected with the drain electrode 175 through the contact hole 185 at the extension 197 to receive a data voltage from the drain electrode 175.

The TFT Q and the pixel electrode 191 described above are just described as exemplary embodiments, and a structure of the TFT and a design of the pixel electrode may be modified in order to improve side visibility.

A lower alignment layer 11 is disposed on the pixel electrode 191. An upper alignment layer 21 is disposed under the common electrode 270 to face the lower alignment layer 11.

In an exemplary embodiment, the lower alignment layer 11 and the upper alignment layer 21 may be vertical alignment layers. In an exemplary embodiment, the alignment layers 11 and 21 may include at least one among generally-used materials as a liquid crystal alignment layer such as polyamic acid, polysiloxane, or polyimide.

A microcavity 305 is defined between the lower alignment layer 11 and the upper alignment layer 21. The microcavity 305 may be defined in one pixel area or may be provided throughout two adjacent pixel areas. A liquid crystal layer is provided inside the microcavity 305.

The liquid crystal layer includes a liquid crystal material including liquid crystal molecules 310 and dichroic dyes 320 combined therewith. The dichroic dye is a guest that is combined to the liquid crystal material as a host, and hereafter a material of which the dichroic dye is combined with the liquid crystal material is referred to as a host-guest liquid crystal material. A color represented by the dichroic dye is determined by a spectrum that is not absorbed by the dichroic dye, that is, a complementary color. Accordingly, when any pixel is intended to display one among primary colors such as red, green, and blue, the dichroic dye included in the liquid crystal layer of the corresponding pixel may be a material absorbing light of a wavelength range corresponding to one among cyan, magenta, and yellow. In an exemplary embodiment, each liquid crystal layer of a red pixel, a green pixel, and a blue pixel may include the host-guest liquid crystal material of which a cyan dichroic dye, a magenta dichroic dye, and a yellow dichroic dye are respectively combined with the liquid crystal material. In the exemplary embodiment, cyan may be defined by an absorption wavelength range of about 600 nanometers (nm) to about 700 nm, magenta may be defined by the absorption wavelength range of about 500 nm to about 580 nm, and yellow may be defined by the absorption wavelength range of about 430 nm to about 490 nm.

According to an exemplary embodiment of the invention, the color of the pixel is realized by the dichroic dye included in the liquid crystal layer, therefore it does not need to provide a color filter. Accordingly, a photolithography process is also not required such that a process step and time to provide the color filter may be reduced and manufacturing cost may be reduced.

When any pixel displays one of cyan, magenta, and yellow, the dichroic dye included in the liquid crystal layer of the corresponding pixel may be a material absorbing the wavelength range corresponding to one of red, green, and blue.

In an exemplary embodiment, the dichroic dye may include at least one of azo dyes, anthraquinone dyes, perylene dyes, merocyanine dyes, azomethine dyes, phthaloperylene dyes, indigo dyes, dioxadine dyes, polythiophene dyes, and phenoxazine dyes, for example, but it is not limited thereto.

An appropriate concentration at which the dichroic dye is combined with the liquid crystal material may be different according to an absorption capacity of the dichroic dye. In an exemplary embodiment, the dichroic dye may be combined with the liquid crystal material at a concentration of about 0.1 wt % to about 15 wt % with respect to a total weight of the liquid crystal layer.

An injection hole 307 is defined in the microcavity 305 to inject a host-guest material for providing the liquid crystal layer.

The microcavity 305 may be defined in a column direction, that is, a vertical direction, of the pixel electrode 191. In the exemplary embodiment, the alignment material providing the alignment layers 11 and 21 and the host-guest liquid crystal material including the liquid crystal molecules 310 and the dichroic dye 320 may be injected into the microcavity 305 by using capillary force, for example.

The microcavity 305 is divided in a vertical direction in a plan view by a plurality of injection hole defining regions 307FP positioned at a portion overlapping the gate line 121, and a plurality of microcavities 305 may be provided along the direction in which the gate line 121 is extended.

A common electrode 270 and a lower insulating layer 350 are positioned on the upper alignment layer 21. The common electrode 270 receives the common voltage, and generates an electric field together with the pixel electrode 191 to which the data voltage is applied to determine a direction in which the liquid crystal molecules 310 positioned at the microcavity 305 between the two electrodes are inclined. The dichroic dye tends to be arranged corresponding to the movement of the liquid crystal molecules. The common electrode 270 provides a capacitor with the pixel electrode 191 to maintain the received voltage even after the TFT is turned off. In an exemplary embodiment, the lower insulating layer 350 may include a silicon nitride (SiNx) or a silicon oxide (SiOx), for example.

In the exemplary embodiment, it is described that the common electrode 270 is disposed on the microcavity 305, but in another exemplary embodiment, the common electrode 270 is disposed under the microcavity 305, so that liquid crystal driving according to a coplanar electrode mode is possible.

A roof layer 360 is positioned on the lower insulating layer 350. The roof layer 360 serves as a support so that the microcavity 305, which is a space between the pixel electrode 191 and the common electrode 270, is defined. In an exemplary embodiment, the roof layer 360 may include a photoresist, or other organic materials.

The upper insulating layer 370 is provided on the roof layer 360. The upper insulating layer 370 may come into contact with an upper surface of the roof layer 360. In an exemplary embodiment, the upper insulating layer 370 may include the inorganic insulating material such as a silicon nitride (SiNx) or a silicon oxide (SiOx). The upper insulating layer 370 has a function of protecting the roof layer 360 including the organic material, and when necessary, the upper insulating layer 370 may be omitted.

In the exemplary embodiment, a capping layer 390 fills the liquid crystal injection hole formation region 307FP and covers the liquid crystal injection hole 307 of the microcavity 305 exposed by the liquid crystal injection hole defining region 307FP. The capping layer 390 contacts the liquid crystal molecules 310 such that the capping layer 390 may include a material that does not react with the liquid crystal molecules 310, such as parylene.

In an exemplary embodiment, the capping layer 390 may be made as a multilayer such as a dual layer or a triple layer. The dual layer includes two layers including different materials. The triple layer includes three layers, and materials of adjacent layers are different from each other. In an exemplary embodiment, the capping layer 390 may include a layer including the organic insulating material and a layer including the inorganic insulating material.

Although not illustrated in the drawings, a polarizer may be further disposed on upper and lower surfaces of the display device. The polarizer may include a first polarizer and a second polarizer. The first polarizer may be attached to a lower surface of the substrate 110 and the second polarizer may be attached on the capping layer 390.

In the exemplary embodiment, as shown in FIG. 3, a partition wall PWP is positioned between the microcavities 305 adjacent to each other in the transverse direction. The partition wall providing portion PWP may be provided in an extending direction of the data line 171, and may be covered by the roof layer 360. The lower insulating layer 350, the common electrode 270, the upper insulating layer 370, and the roof layer 360 are filled in the partition wall providing portion PWP, and the structure provides the partition wall to partition or define the microcavity 305. When the partition wall structure such as the partition wall providing portion PWP exists between the microcavities 305, even when the insulation substrate 110 is bent, generated stress is small, and a change degree of a cell gap may be considerably reduced.

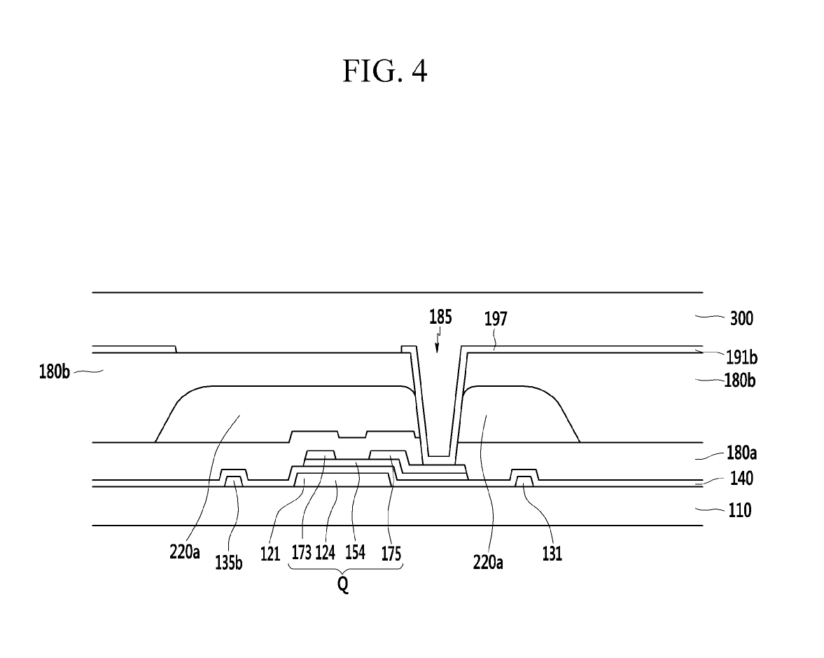

Next, an exemplary embodiment of manufacturing the described display device will be described with reference to FIGS. 4 to 18. The exemplary embodiment described in the following is an exemplary embodiment of the manufacturing method, and thus may be modified in another form and thereby implemented.

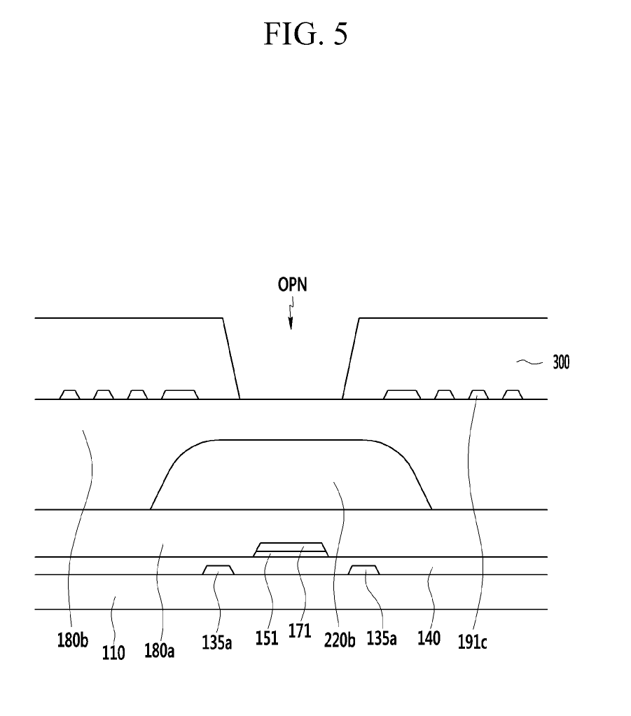

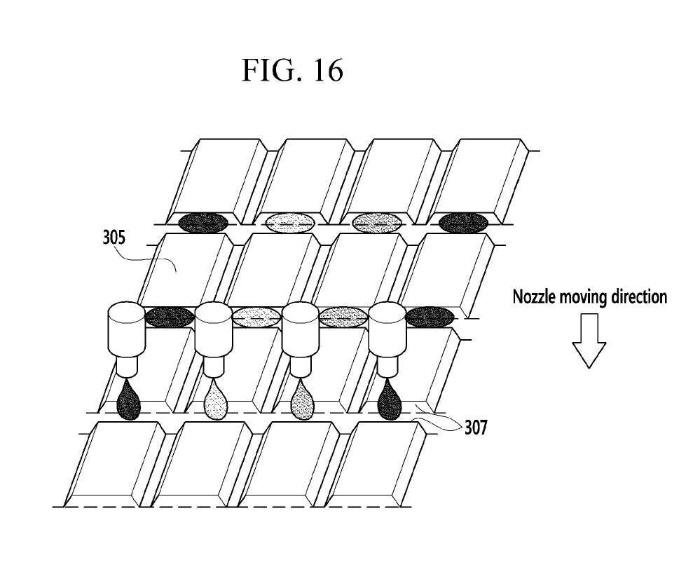

FIGS. 4 to 15 are process cross-sectional views of a method for manufacturing a display device according to an exemplary embodiment of the invention, and FIGS. 16 to 18 are views schematically showing a liquid crystal injection method in a display device according to an exemplary embodiment of the invention. FIGS. 4, 6, 8, 10, 11, 13 and 15 sequentially show the cross-sectional views taken along line II-II of FIG. 1, and FIGS. 5, 7, 9, 12 and 14 sequentially show the cross-sectional views taken along line III-III of FIG. 1.

Referring to FIGS. 1, 4, and 5, in order to provide a switching element on a substrate 110, the gate line 121 extended in the horizontal direction is provided, and the gate insulating layer 140 is disposed on the gate line 121, the semiconductor layers 151 and 154 are disposed on the gate insulating layer 140, and the source electrode 173 and the drain electrode 175 are provided. In this case, the data line 171 connected with the source electrode 173 may be provided to be extended in the vertical direction while crossing the gate line 121. The storage electrode line 131 may also be provided when providing the gate line 121.

The first interlayer insulating layer 180a is disposed on the data conductors 171, 173, and 175 including the source electrode 173, the drain electrode 175, and the data line 171, and the exposed portion of the semiconductor layer 154.

The light blocking member 220a or 220b covering the data conductor is disposed on the first interlayer insulating layer 180a. According to an exemplary embodiment of the invention, a step of providing the color filter is omitted.

The second interlayer insulating layer 180b covering the light blocking member 220a or 220b is disposed thereon. A contact hole 185 is defined in the light blocking member 220a or 220b and the second interlayer insulating layer 180b to electrically and physically connect the pixel electrode 191 and the drain electrode 175.

Next, the pixel electrode 191 is disposed on the second interlayer insulating layer 180b, and a sacrificial layer 300 is disposed on the pixel electrode 191. In an exemplary embodiment, the pixel electrode 191 may be provided by depositing and patterning the transparent conductive material such as ITO and IZO. In an exemplary embodiment, the sacrificial layer 300 may be provided by coating a photosensitive organic material on the pixel electrode 191 and applying a photolithography process, for example. As shown in FIG. 5, an opening OPN is defined in the sacrificial layer 300 along a direction parallel with the data line 171. In a subsequent process, the common electrode 270, the lower insulating layer 350, the roof layer 360, and the upper insulating layer 370 are filled in the open portion OPN to provide the partition wall providing portion PWP.

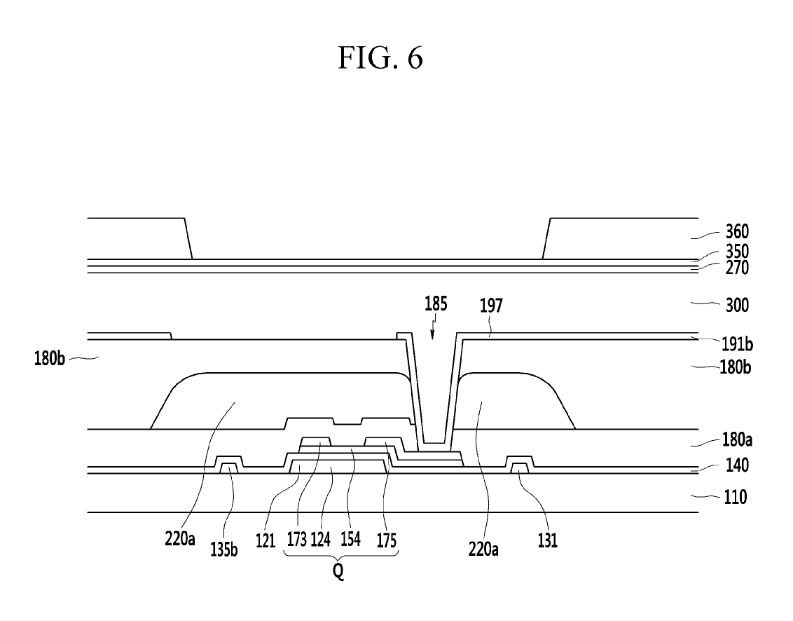

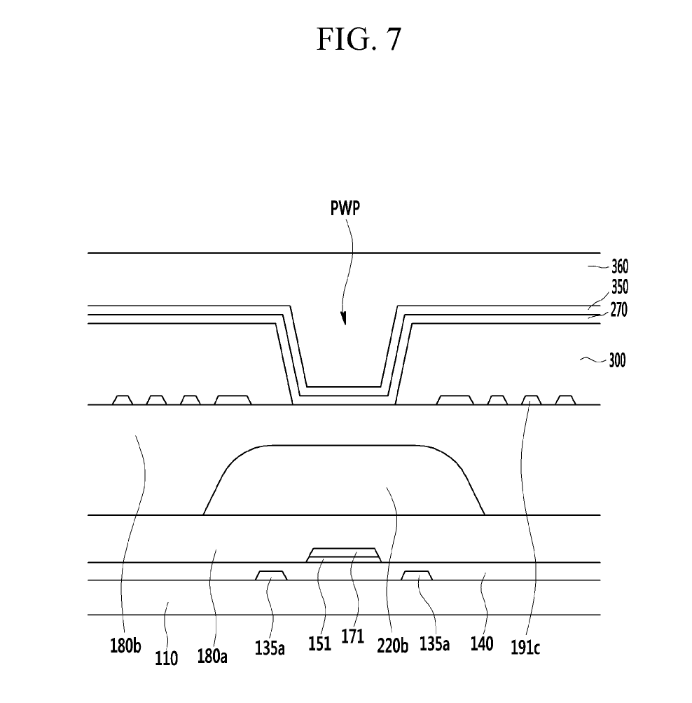

Referring to FIGS. 6 and 7, the common electrode 270, the lower insulating layer 350, and the roof layer 360 are sequentially disposed on the sacrificial layer 300. The roof layer 360 may be removed at the region corresponding to the light blocking member 220a positioned between the pixel areas adjacent in the vertical direction by an exposure and development process. The roof layer 360 exposes the lower insulating layer 350 in the region corresponding to the light blocking member 220. In this case, the common electrode 270, the lower insulating layer 350, and the roof layer 360 fill the open portion OPN on the longitudinal light blocking member 220b thereby providing the partition providing portion PWP.

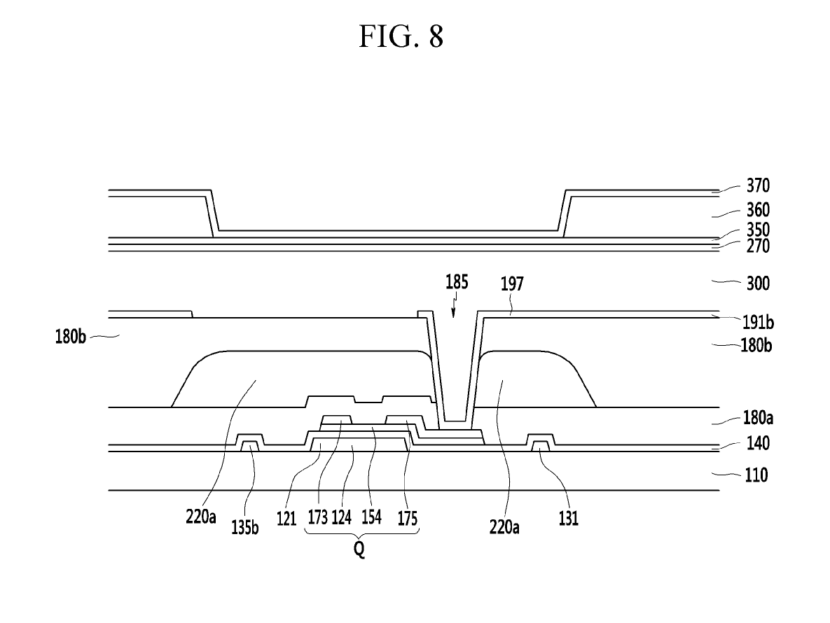

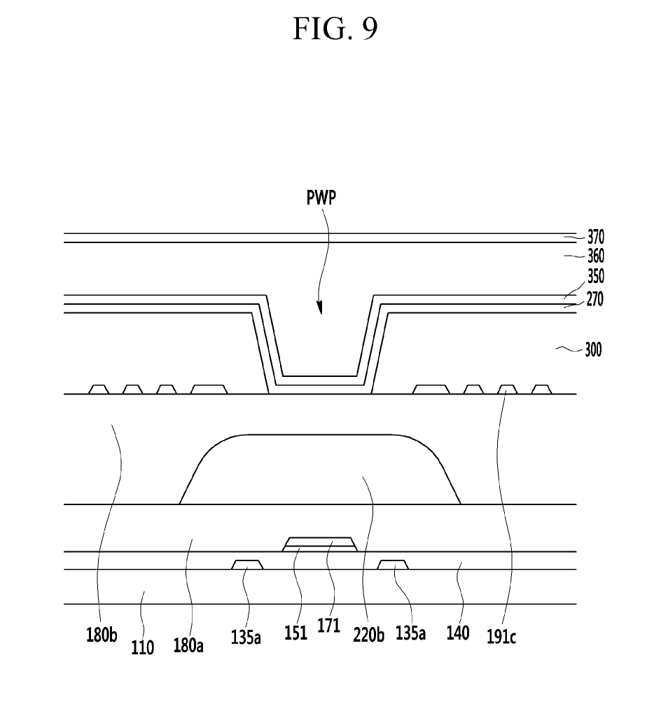

Referring to FIGS. 8 and 9, the upper insulating layer 370 is provided in such a way so as to cover upper portions of the roof layer 360 and the exposed lower insulating layer 350.

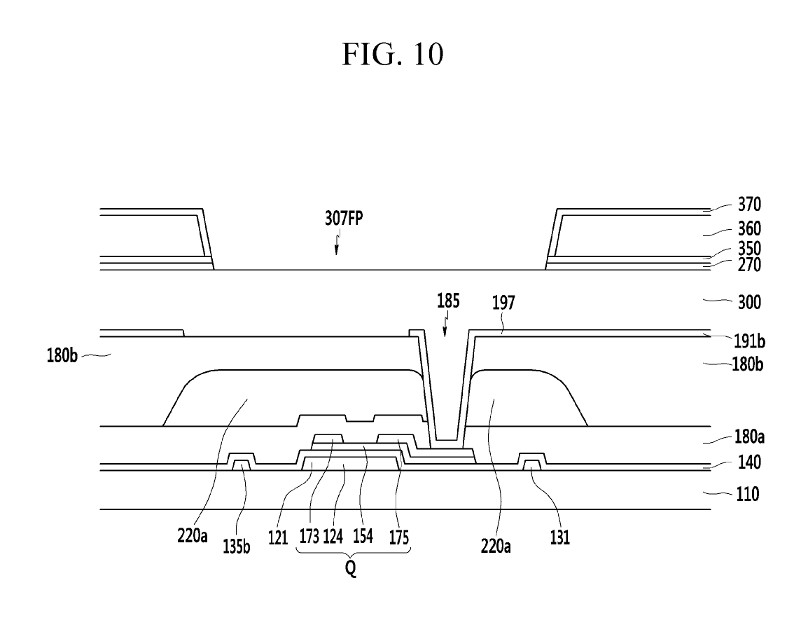

Referring to FIG. 10, the upper insulating layer 370, the lower insulating layer 350, and the common electrode 270 are dry-etched to partially remove the upper insulating layer 370, the lower insulating layer 350, and the common electrode 270, thereby providing the injection hole defining region 307FP. In this case, the upper insulating layer 370 may have a structure that covers a side surface of the roof layer 360, but is not limited thereto. In an exemplary embodiment, the upper insulating layer 370 covering the side surface of the roof layer 360 may be removed so that the side surface of the roof layer 360 may be externally exposed.

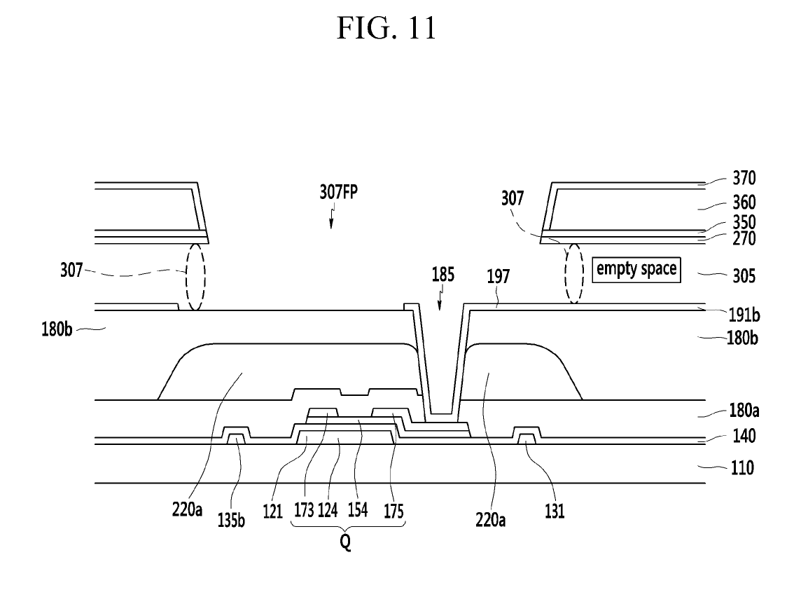

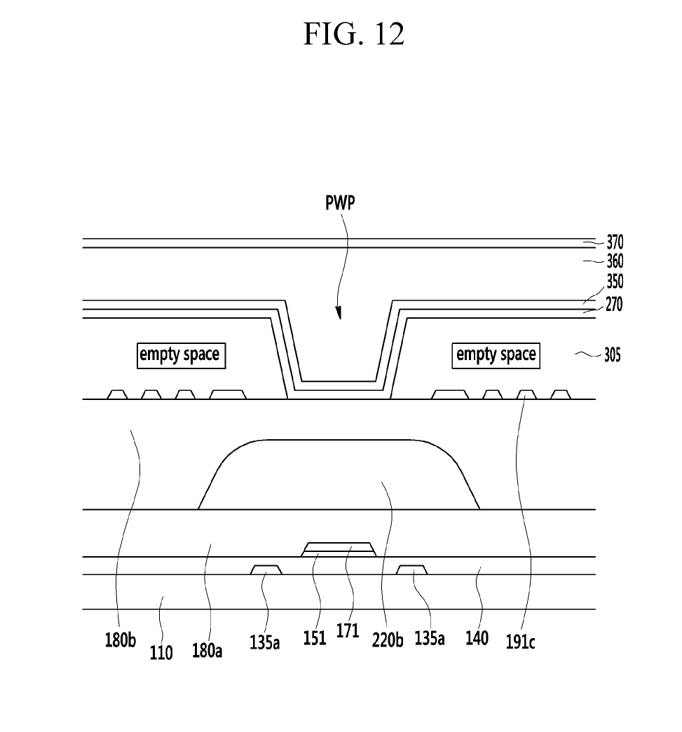

Referring to FIGS. 11 and 12, the sacrificial layer 300 is removed by an oxygen (O2) ashing process or a wet-etching method, for example, through the injection hole defining region 307FP. In this case, the microcavities 305 having the injection holes 307 are defined. The microcavities 305 are an empty space according to the removal of the sacrificial layer 300. In an exemplary embodiment, to maintain the shape of the microcavity 305, a process of hardening the roof layer 360 may be performed by heating, for example.

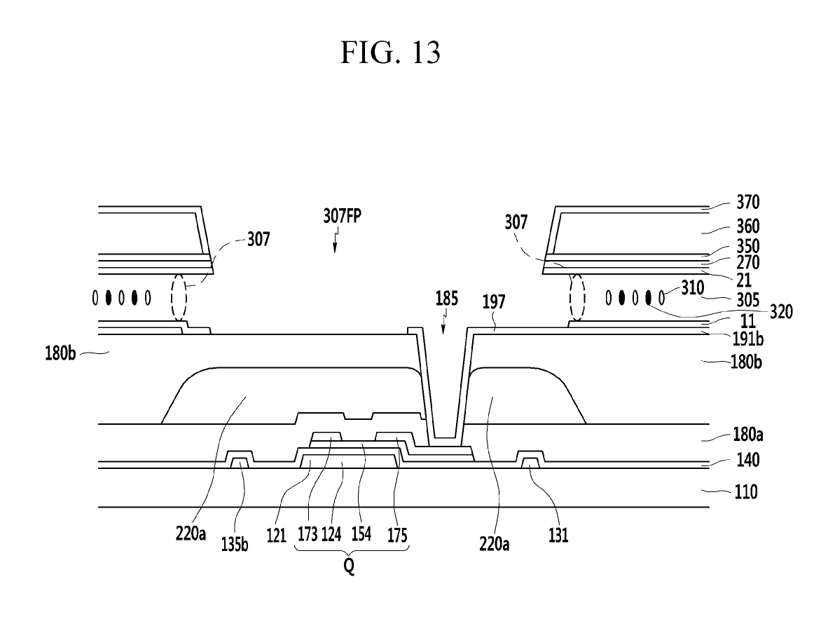

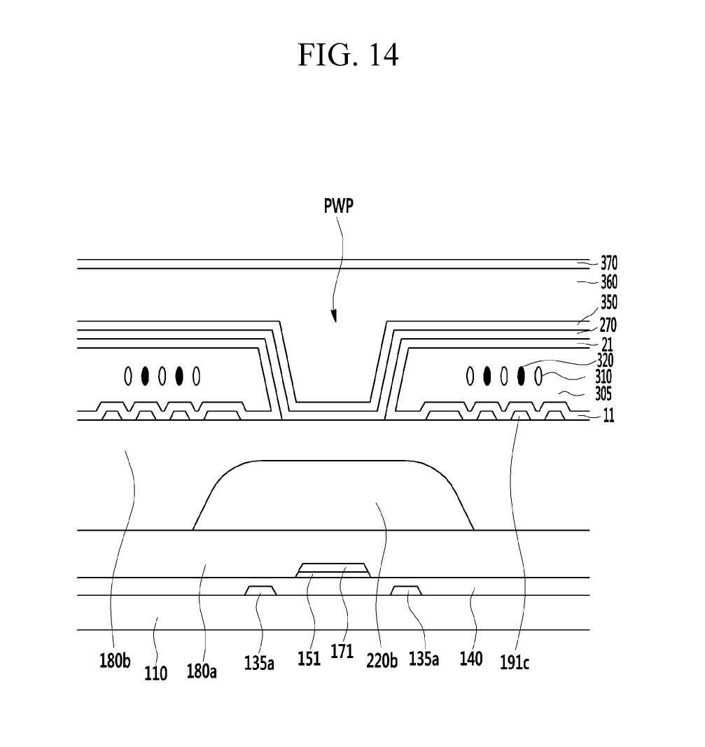

Referring to FIGS. 13 and 14, the alignment layers 11 and 21 are respectively disposed on the pixel electrode 191 and the common electrode 270 by injecting an aligning material through the injection holes 307. In detail, when an aligning agent including an alignment material is dripped on the substrate 110 by a spin coating method or an inkjet method, for example, the aligning agent is injected into the microcavity 305 through the injection holes 307. Next, when performing a hardening process, a solution component is evaporated and the alignment material remains at an inner wall of the microcavity 305, thereby providing the alignment layers 11 and 21.

Next, the host-guest liquid crystal material including the liquid crystal molecules 310 and the dichroic dye 320 is injected into the microcavity 305 through the injection hole 307 by using an inkjet method. To display the different colors for each pixel, the injection of the host-guest liquid crystal material may be performed by various methods that are exemplified in FIGS. 16 to 18.

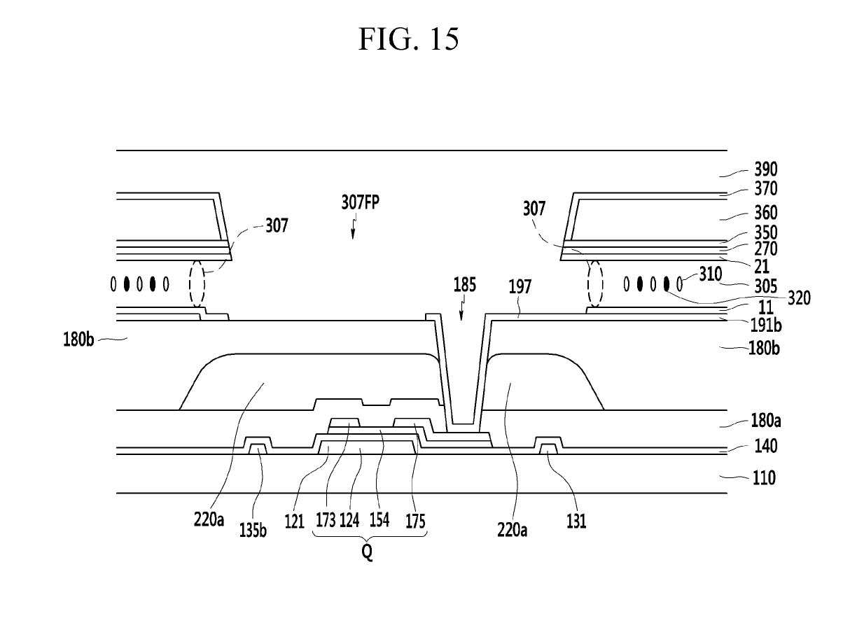

Referring to FIG. 15, the capping layer 390 fills the liquid crystal injection hole formation region 307FP, which will be described in detail later.

Referring to FIG. 16, the same host-guest liquid crystal material displaying the same color in the longitudinal direction is injected to the microcavity 305 through the injection holes 307 defined at both sides of the microcavity 305, and the host-guest liquid crystal materials of the different kinds displaying the different colors are repeatedly injected to the adjacent microcavities 305 in the transverse direction through the injection holes 307 with a predetermined cycle (e.g., repetition of red, green, and blue). Nozzles injecting the host-guest liquid crystal materials of the different kinds may drip the host-guest liquid crystal materials while being moved in the longitudinal direction, as an example. At this time, the injection process for each color is performed with a time gap so that the host-guest liquid crystal materials of the different kinds are not combined with each other, the injection processes are simultaneously performed while controlling a spread of the host-guest liquid crystal materials, or combination of the two methods may be performed.

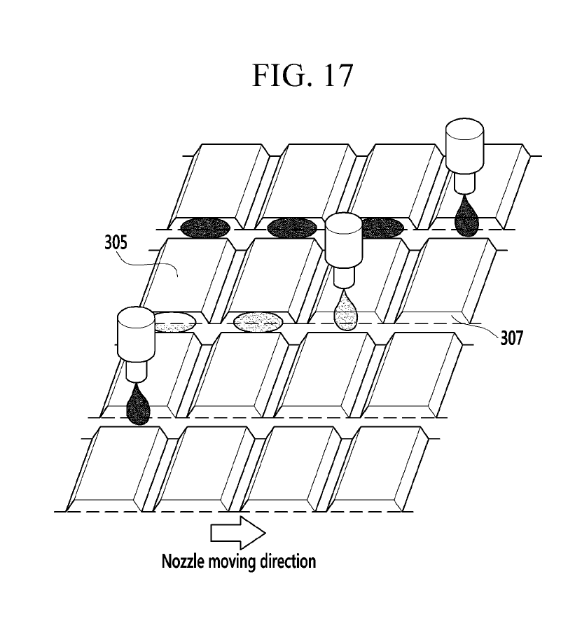

Referring to FIG. 17, the same host-guest liquid crystal material displaying the same color in the transverse direction is injected to the microcavities 305 through the injection holes 307, and the host-guest liquid crystal materials of the different kinds displaying the different colors are repeatedly injected to the adjacent microcavities 305 in the longitudinal direction through the injection holes 307 with a predetermined cycle. The nozzles injecting the host-guest liquid crystal materials of the different kinds may drip the host-guest liquid crystal materials while being moved in the transverse direction, as an example.

To prevent the host-guest liquid crystal materials of the different kinds from being injected into one microcavity 305, one of the injection holes 307 of both sides of the microcavity 305 may be substantially blocked so that the host-guest liquid crystal material is not injected. As one way of this method, a supporter (not shown) supporting the roof layer 360 may be provided at the side of one injection hole among the injection holes 307 of both sides of the microcavity 305 to induce a gathering of the alignment layer at the injection hole, and thereby the injection hole may be blocked by the gathering of the alignment layer. Here, the gathering of the alignment layer means that a solid is gathered in one position in a dry process of the aligning agent and then the alignment material is agglomerated. Alternatively, when providing the light blocking member 220 or the second interlayer insulating layer 180b, a portion of them may be provided to be protruded toward one injection hole by using a minute slit exposure method.

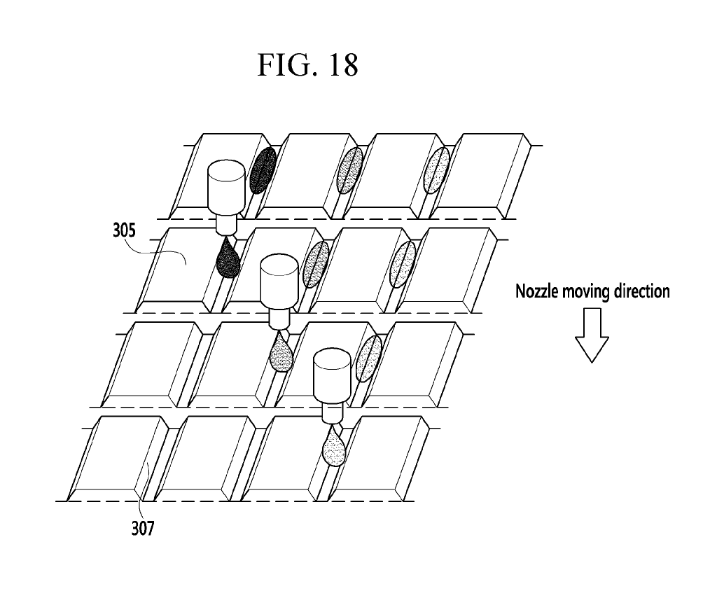

Referring to FIG. 18, like the exemplary embodiment of FIG. 16, the same host-guest liquid crystal material displaying the same color in the longitudinal direction is injected to the microcavities 305 through the injection holes 307, and the host-guest liquid crystal materials of the different kinds displaying the different colors are repeatedly injected to the adjacent microcavities 305 in the transverse direction through the injection holes 307 with a predetermined cycle. Also, the nozzles injecting the host-guest liquid crystal materials of the different kinds may drip the host-guest liquid crystal materials while being moved in the longitudinal direction, as an example. As a difference, in the exemplary embodiment of FIG. 16, for example, as shown in FIG. 2, the host-guest liquid crystal material is injected through the injection holes 307 defined at both upper and lower sides of the microcavity 305, however, in the exemplary embodiment of FIG. 18, the host-guest liquid crystal material is injected through the injection hole 307 defined at one side (a right side or a left side) of the microcavity 305.

Referring to FIG. 15, a material that does not react with the liquid crystal molecules 310 is deposited to provide the capping layer 390. The capping layer 390 is provided to cover the injection holes 307 through which the microcavities 305 are externally exposed to seal the microcavities 305.

Next, although not shown, a polarizer may be attached at upper and lower surfaces of the display device. The polarizer may include a first polarizer and a second polarizer. The first polarizer may be attached to the lower surface of the substrate 110 and the second polarizer may be attached on the capping layer 390.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a substrate;
a thin film transistor which is positioned on the substrate;
a pixel electrode positioned on the thin film transistor and connected to the thin film transistor;
a roof layer separated from the pixel electrode via a microcavity interposed therebetween; and
a liquid crystal layer positioned in the microcavity and including a liquid crystal material and a dichroic dye.

2. The display device of claim 1, wherein
the dichroic dye is at a concentration of about 0.1 wt % to about 15 wt % with respect to a total weight of the liquid crystal layer.

3. The display device of claim 1, wherein
the dichroic dye is a material which absorbs a wavelength range corresponding to one of cyan, magenta, and yellow.

4. The display device of claim 3, wherein
the dichroic dye includes at least one of azo dyes, anthraquinone dyes, perylene dyes, merocyanine dyes, azomethine dyes, phthaloperylene dyes, indigo dyes, dioxadine dyes, polythiophene dyes, and phenoxazine dyes.

5. The display device of claim 4, wherein
injection holes are respectively defined at facing edges of the microcavity.

6. The display device of claim 5, wherein
one of the injection holes of the microcavity is substantially blocked so that a material providing the liquid crystal layer is not injectable therein.

7. The display device of claim 1, wherein
a plurality of microcavities is disposed in a matrix form,
the liquid crystal layer including a first dichroic dye configured to display a color is positioned in microcavities of the plurality of microcavities adjacent in a column direction, and
the liquid crystal layer including a second dichroic dye configured to display a different color from the first dichroic dye is positioned in microcavities of the plurality of microcavities adjacent in a row direction.

8. The display device of claim 1, wherein
a plurality of microcavities is disposed in a matrix form,
the liquid crystal layer including a first dichroic dye configured to display a color is positioned in microcavities of the plurality of microcavities adjacent in a row direction, and
the liquid crystal layer including a second dichroic dye configured to display a different color from the first dichroic dye is positioned in microcavities of the plurality of microcavities adjacent in a column direction.

9. The display device of claim 1, further comprising
a common electrode positioned between the microcavity and the roof layer.

10. A method of manufacturing a display device, comprising:
disposing a thin film transistor on a substrate;
providing a pixel electrode connected to the thin film transistor;
disposing a sacrificial layer on the pixel electrode;
disposing a roof layer on the sacrificial layer;
removing the sacrificial layer to define injection holes of a microcavity; and
injecting a combination material of which a dichroic dye is combined with a liquid crystal material through the injection holes to provide a liquid crystal layer in the microcavity.

11. The method of claim 10, wherein
the dichroic dye is at a concentration of about 0.1 wt % to about 15 wt % with respect to a total weight of the liquid crystal layer.

12. The method of claim 10, wherein
the dichroic dye is a material which absorbs a wavelength range corresponding to one of cyan, magenta, and yellow.

13. The method of claim 12, wherein
the dichroic dye includes at least one of azo dyes, anthraquinone dyes, perylene dyes, merocyanine dyes, azomethine dyes, phthaloperylene dyes, indigo dyes, dioxadine dyes, polythiophene dyes, and phenoxazine dyes.

14. The method of claim 13, wherein
the combination material is injected through the injection holes respectively positioned at facing edges of the microcavity.

15. The method of claim 13, wherein
the combination material is injected through one of the injection holes of the microcavity.

16. The method of claim 10, wherein
the microcavity is in a matrix form, and the combination material is injected according to a row direction.

17. The method of claim 10, wherein
the microcavity is in a matrix form, and the combination material is injected according to a column direction.

18. The method of claim 10, further comprising
disposing a common electrode on the sacrificial layer before the disposing the roof layer on the sacrificial layer.
